(19) United States
(12) Patent Application Publication
(10) Pub. No.: US 2014/0287564 A1
(43) Pub. Date: Sep. 25, 2014

(54) Semiconductor Devices Having Shallow Junctions

(71) Applicant: Samsung Electronics Co., Ltd., Suwon-si (KR)

(72) Inventors: Keum-Seok Park, Seongnam-si (KR); Seung-Hun Lee, Seoul (KR); Byeong-Chan Lee, Yongin-si (KR); Sang-Bom Kang, Seoul (KR); Hong-Bum Park, Seongnam-si (KR)

(73) Assignee: Samsung Electronics Co., Ltd., Suwon-si (KR)

(21) Appl. No.: 14/287,546

(22) Filed: May 27, 2014

Related U.S. Application Data
(63) Continuation of application No. 13/271,615, filed on Oct. 12, 2011.

(30) Foreign Application Priority Data
Oct. 13, 2010 (KR) 10-2010-0099825

(51) Int. Cl. H01L 29/66; H01L 29/08

(52) U.S. Cl. CPC H01L 29/66621; H01L 29/0847
USPC 438/285

(57) ABSTRACT

Semiconductor devices are provided including a substrate having a first surface and a second surface recessed from opposite sides of the first surface, a gate pattern formed on the first surface and having a gate insulating layer and a gate electrode, a carbon-doped silicon buffer layer formed on the second surface, and source and drain regions doped with an n-type dopant or p-type dopant, epitaxially grown on the silicon buffer layer to be elevated from a top surface of the gate insulating layer.

### CLAIM OF PRIORITY

This application is a continuation of U.S. application Ser. No. 13/271,615, filed Oct. 12, 2011, which application claims priority from Korean Patent Application No. 10-2010-0099825, filed Oct. 13, 2010, the contents of which are hereby incorporated herein by reference as if set forth in their entirety.

### FIELD

The present inventive concept relates generally to semiconductor devices and related methods and, more particularly to semiconductor devices having ultra shallow junctions and related methods.

### BACKGROUND

With the recent trend toward high integration, semiconductor devices have been gradually scaled down in size. As a result, methods to integrate an increased number of transistors in a unit chip have been implemented.

Metal-on-silicon (MOS) transistors are widely used as discrete devices of the semiconductor devices. Recently, to meet the scaling-down requirement, MOS transistors having ultra shallow junctions have been developed. To form an ultra shallow junction, an elevated source/drain (ESD) structure has been proposed. In the ESD structure, however, an accurate junction depth can not typically be attained due to diffusion of a dopant. Furthermore, the extent to which thicknesses of the source/drain can be adjusted may be limited due to a height of the gate. Furthermore, a channel length of the semiconductor device may be reduced due to lateral diffusion of a dopant, which may cause a short channel effect, thereby possibly degrading device characteristics.

### SUMMARY

Some embodiments of the present inventive concept provide a semiconductor device including a substrate having a first surface and a second surface recessed from opposite sides of the first surface; a gate pattern formed on the first surface and having a gate insulating layer and a gate electrode; a carbon-doped silicon buffer layer formed on the second surface; and source and drain regions doped with an n-type dopant or p-type dopant, epitaxially grown on the silicon buffer layer to be elevated from a top surface of the gate insulating layer.

In further embodiments, there is provided a semiconductor device including a substrate having a first surface and a second surface recessed from opposite sides of the first surface, a gate pattern formed on the first surface and having a gate insulating layer and a gate electrode, a carbon-doped silicon buffer layer formed on the second surface, source and drain regions doped with an n-type dopant or p-type dopant, epitaxially grown on the silicon buffer layer, and an epitaxial silicon layer doped with an n-type or p-type dopant, epitaxially grown on the source region and the drain region to be elevated from a top surface of the gate insulating layer.

In still further embodiments, there is provided a manufacturing method of a semiconductor device, the method including forming a gate pattern and a gate spacer disposed at sidewalls of the gate pattern on a substrate, the gate pattern including a gate insulating layer and a gate electrode, forming a recessed surface by etching the substrate of opposite sides of the gate pattern and the gate spacer, forming a carbon-doped silicon buffer layer on the recessed surface, and forming source and drain regions doped with an n-type dopant or a p-type dopant on the silicon buffer layer using selective epitaxial growth.

Since the semiconductor device according to the present inventive concept has an ultra shallow junction structure, it can be advantageously scaled down.

Since dopant diffusion is adjusted, an accurate junction depth can be achieved and degradation of device characteristics due to a short channel effect can be prevented.

Furthermore, since excessive diffusion of the dopant is reduced or possibly prevented, current leakage can be reduced.

An ion implantation process may be omitted, so that damages that may occur to a crystalline structure during the ion implantation process can be avoided and dopant diffusion can be reduced.

Since the semiconductor device according to the present inventive concept further includes a doped silicon layer on the source/drain regions, contact resistance can be reduced.

### BRIEF DESCRIPTION OF THE DRAWINGS

The above and other features and advantages of the present inventive concept will become more apparent by describing in detail preferred embodiments thereof with reference to the attached drawings in which:

FIG. 1 is a cross-section illustrating a semiconductor device according to some embodiments of the present inventive concept.

FIG. 2 is a cross-section illustrating a semiconductor device according to some embodiments of the present inventive concept.

FIG. 3 is a flowchart illustrating processing steps in the fabrication of a semiconductor device according to some embodiments of the present inventive concept.

FIGS. 4 through 8 are cross-sections illustrating processing steps in the fabrication of a semiconductor device according to some embodiments of the present inventive concept.

FIG. 9 is a graph illustrating measurement results of current leakage levels depending on structures of semiconductor devices in accordance with some embodiments of the present inventive concept.

FIG. 10 illustrates is a graph illustrating measurement results of overall concentrations of phosphorus (P) doped by selective epitaxial growth and concentrations of activated phosphorus (P) in accordance with some embodiments of the present inventive concept.

### DETAILED DESCRIPTION

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. In the drawings, the thickness of layers and regions are exaggerated for clarity.

It will be understood that when an element or layer is referred to as being “on or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sections by way of ideal schematic views of the inventive concept. Accordingly, the exemplary views may be modified depending on manufacturing technologies and/or tolerances. Therefore, the embodiments of the inventive concept are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

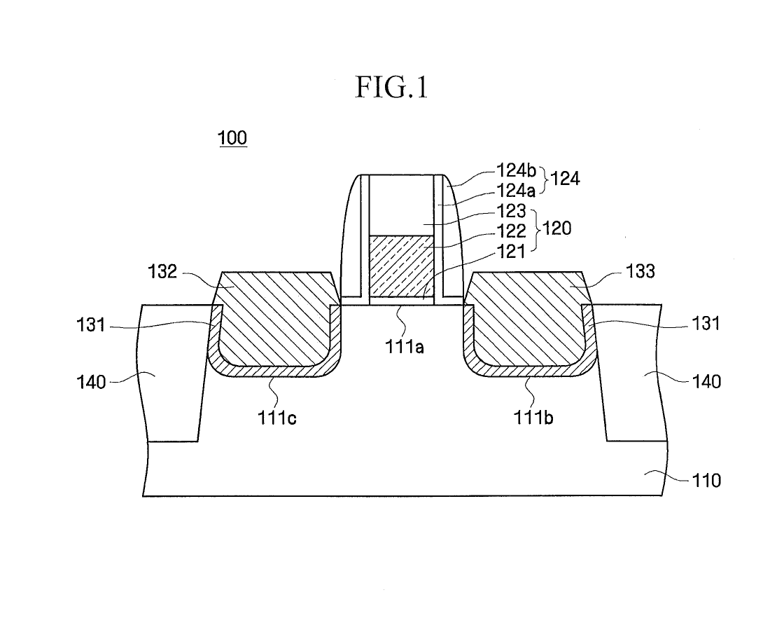

Referring now to FIG. 1, a cross-section of a semiconductor device according to some embodiments of the present inventive concept will be discussed. As illustrated in FIG. 1, the semiconductor device 100 according to some embodiments of the present inventive concept includes a substrate 110, a gate pattern 120, a gate spacer 124, a silicon buffer layer 131, a source region 132 and a drain region 133.

The substrate 110 may be a silicon substrate, an SOI (Silicon On Insulator) substrate, a gallium arsenic substrate, a silicon germanium (SiGe) substrate, a ceramic substrate, a quartz substrate, or a glass substrate for a display. Although not shown, the substrate 110 may a p-type well or an n-type well doped with a p-type or an n-type impurity, respectively.

As illustrated in FIG. 1, the substrate 110 may be divided into an active region and a non-active region by an isolation layer 140. The semiconductor device is formed on the active region defined by the isolation layer 140. The isolation layer 140 may be formed by, for example, a shallow trench isolation (STI) or a field oxide (FOX) technique.

The active region defined by the isolation layer 140 is divided into a first surface 111a and second surfaces 111b and 111c. On the first surface 111a is formed a gate pattern 120, which will be discussed in detail below, and a channel is formed thereunder. The second surfaces 111b and 111c are formed such that the substrate 110 is recessed from opposite sides of the first surface 111a. In particular, the second surfaces 111b and 111c are formed such that the substrate 110 is recessed to a depth of 10 nm to 50 nm from the opposite sides of the first surface 111a. When the second surfaces 111b and 111c are recessed within the above-noted range, the short channel effect and current leakage can be reduced, and shallow junctions can be formed by forming a source and a drain at the recessed regions.

The gate pattern 120 is formed on the first surface 111a and may have a stacked structure having a gate insulating layer 121, a gate electrode 122 and a hard mask layer 123 sequentially stacked. While the gate pattern 120 of FIG. 1 includes the gate insulating layer 121, the gate electrode 122 and the hard mask layer 123, embodiments of the present inventive concept are not limited to this configuration. For example, the hard mask layer 123 may be omitted without departing from the scope of the present inventive concept.

The gate insulating layer 121 is formed on the first surface 111a and may be formed of an insulating material, such as silicon oxide (SiOₓ), silicon oxynitride (SiON), titanium oxide (TiOₓ), or tantalum oxide (TaOₓ).

The gate electrode 122 is formed on the gate insulating layer. The gate electrode 122 is a conductor and may have a stacked structure of at least one of an n-type or p-type impurity doped polysilicon layer, a metal layer, a metal silicide layer, or a metal nitride layer. Examples of the useful metal for the gate electrode 122 may include, but not limited to, cobalt (Co), nickel (Ni), titanium (Ti), and tantalum (Ta). The hard mask layer 123 may be formed on the gate electrode 122 using an insulating material.

The gate spacer 124 is formed on the sidewalls of the gate pattern 120 and protects side surfaces of the gate electrode 122. The gate spacer 124 may be formed of an oxide layer or a nitride layer, or may have a dual layered structure of an oxide layer and a nitride layer. FIG. 1 illustrates that the gate spacer 124 has a dual layered structure of an oxide layer 124a and a nitride layer 124b. The oxide layer 124a is formed on the sidewalls of the gate pattern 120 and extends toward the active region of the substrate 110. The nitride layer 124b is formed on the sidewalls of the gate pattern 120 while covering the entire surface of the oxide layer 124a.

The silicon buffer layer 131 is formed on the second surfaces 111b and 111c. The silicon buffer layer 131 may reduce or possibly prevent diffusion of a dopant implanted into the source region 132 and the drain region 133, which will be discussed below, thereby accurately adjusting a junction depth and reducing current leakage due to dopant diffusion. Furthermore, the silicon buffer layer 131 reduces the likelihood that or possibly prevents the dopant from being laterally diffused, thereby reducing the likelihood that or possibly preventing device characteristics from degrading due to a punch through phenomenon and a short channel effect.

The silicon buffer layer 131 may be made of a carbon-containing material. Specifically, the silicon buffer layer 131 may be made of carbon-doped silicon. A silicon layer that is not doped with carbon may prevent generation of a stacking fault due to a mismatch of its lattice structure or may prevent abnormal growth of a source region and a drain region during epitaxial growth. However, the carbon-doped silicon buffer layer 131 according to some embodiments of the present inventive concept may further suppress diffusion of the dopant existing in the source region 132 and the drain region 133.

The silicon buffer layer 131 may be formed by selective epitaxial growth (SEG) or carbon ion implantation into silicon. The silicon buffer layer 131 may be made of a material containing silicon carbide (SiC) prepared by selective epitaxial growth. Furthermore, the silicon buffer layer 131 may be formed to a thickness of 1 nm to 20 nm using selective epitaxial growth. When the silicon buffer layer 131 is epitaxially grown to the thickness in the above-noted range, dopant diffusion can be effectively reduced or possibly prevented, thereby achieving an accurate junction depth, and enhancing the mobility of carriers by applying tensile stress to a channel region.

The source region 132 and the drain region 133 are formed on the silicon buffer layer 131, and are formed higher than a top surface of the gate insulating layer 121, as shown in FIG. 1. When the source region 132 and the drain region 133 are formed to have an elevated source/drain structure in which top surfaces of the source region 132 and the drain region 133 are higher than the top surface of the gate insulating layer 121, ultra shallow junctions can be formed.

In particular, the top surfaces of the source region 132 and the drain region 133 are at least 20 nm higher than the top surface of the gate insulating layer 121 and lower than the top surface of the gate electrode 122.

The source region 132 and the drain region 133 may be filled with a silicon-containing material doped with an n-type dopant or a p-type dopant prepared by selective epitaxial growth.

In particular, for example, in embodiments of an NMOS device, the source region 132 and the drain region 133 may be formed by doping an n-type dopant, such as phosphorous (P) while implanting a silicon (Si) containing material by selective epitaxial growth. In embodiments of a PMOS device, the source region 132 and the drain region 133 may be formed by doping a p-type dopant such as boron (B) while implanting a silicon (Si) containing material by selective epitaxial growth. In particular, in the NMOS device, the source region 132 and the drain region 133, which are doped with phosphorous (P), can be formed by performing selective epitaxial growth while simultaneously implanting a silicon (Si) source gas and a P source gas. In the PMOS device, the source region 132 and the drain region 133, which are doped with boron (B) in a silicon germanium (SiGe) layer, can be formed by performing selective epitaxial growth while simultaneously implanting a silicon (Si) source gas, a germanium (Ge) source gas and a boron source gas. Since the silicon germanium (SiGe) layer applies compressive stress to a channel to increase the mobility of holes, it can be advantageously adapted to a PMOS device.

When the source region 132 and the drain region 133 are doped with an n-type dopant, i.e., phosphorous (P), a concentration of the impurity may be in a range of from about 1.0×10¹⁹ to about 1.0×10²¹ atoms/cc. If the source region 132 and the drain region 133 are doped at a concentration higher than 1.0×10¹⁹ atoms/cc, resistance may be reduced and the flow of current may increase. If the source region 132 and the drain region 133 are doped at a concentration lower than 1.0×10²¹ atoms/cc, impurity diffusion may be reduced, so that the current leakage may decrease.

A channel through which current flows is formed between the source region 132 and the drain region 133.

The silicon buffer layer 131 is formed in situ with the formation of the source region 132 and the drain region 133. That is to say, after the silicon buffer layer 131 is formed by selective epitaxial growth, the source region 132 and the drain region 133 are subjected to selective epitaxial growth performed in situ within the same chamber with a variation of a source gas. Since the forming of the silicon buffer layer 131 and the source region 132 and the drain region 133 are performed in situ, the process is simplified, and introduction of impurity can be reduced or possibly prevented.

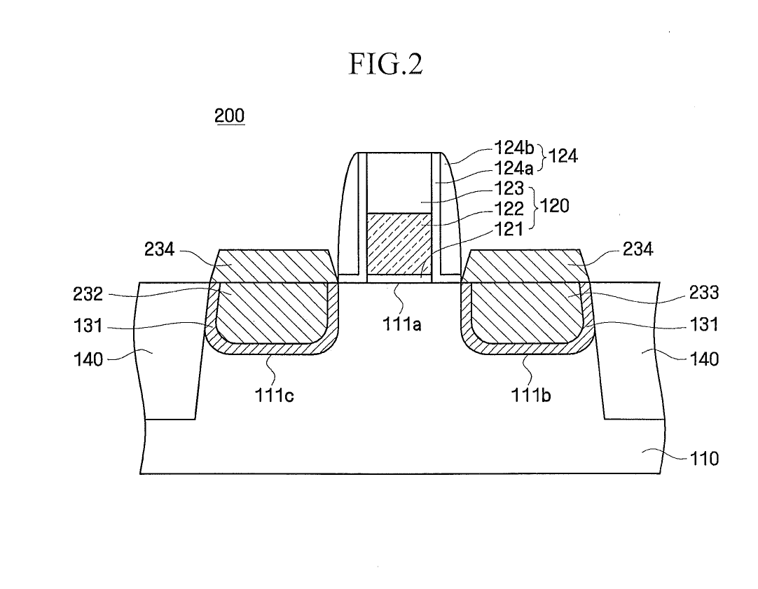

Referring now to FIG. 2, a cross-section of a semiconductor device according to some embodiments of the present inventive concept will be discussed. For convenience of explanation, the same functional components as those shown in FIG. 1 are denoted by the same reference numerals, and a detailed description thereof will be omitted.

As illustrated in FIG. 2, the semiconductor device 200 according to some embodiments of the present inventive concept includes a substrate 110, a gate pattern 120, a gate spacer 124, a silicon buffer layer 131, a source region 232, a drain region 233 and an epitaxial silicon layer 234. The semiconductor device 200 according to some embodiments of the present inventive concept is substantially the same as the semiconductor device 100 according to embodiments discussed above with respect to FIG. 1, except that the epitaxial silicon layer 234 is formed. Thus, the following description will focus on the epitaxial silicon layer 234.

The source region 232 and the drain region 233 may be formed on the silicon buffer layer 131 by selective epitaxial growth. The source region 232 and the drain region 233 may be formed at the same height as the first surface 111a or lower than a top surface of a gate insulating layer 121 by selective epitaxial growth. Since the semiconductor device 200 according to some embodiments of the present inventive concept further includes the epitaxial silicon layer 234, it is not necessary for the source region 232 and the drain region 233 to be higher than the top surface of the gate insulating layer 121.

The epitaxial silicon layer 234 is formed on the source region 232 and the drain region 233 to be higher than the top surface of the gate insulating layer 121. In particular, the epitaxial silicon layer 234 is formed at least 20 nm higher than the top surface of the gate insulating layer 121 and lower than a top surface of a gate electrode 122.

The epitaxial silicon layer 234 may be made of an n-type dopant or a p-type dopant prepared by selective epitaxial growth and may be made of the same material with the source region 232 and the drain region 233. In particular, in embodiments of an NMOS device, the epitaxial silicon layer 234 may be formed by performing selective epitaxial growth while doping an n-type dopant, such as phosphorous (P) into silicon. In embodiments of a PMOS device, the epitaxial silicon layer 234 may be formed by doping a p-type dopant such as boron (B) while performing selective epitaxial growth on a silicon germanium (SiGe) layer. Here, a dopant concentration of the epitaxial silicon layer 234 may be equal to or higher than that of the source region 232 and the drain region 233. If the dopant concentration of the epitaxial silicon layer 234 is higher than that of the source region 232 and the drain region 233, the flow of current may be increased by reducing contact resistance.

The epitaxial silicon layer 234 may have a multi-layered structure by varying dopant concentrations as demanded by one skilled in the art.

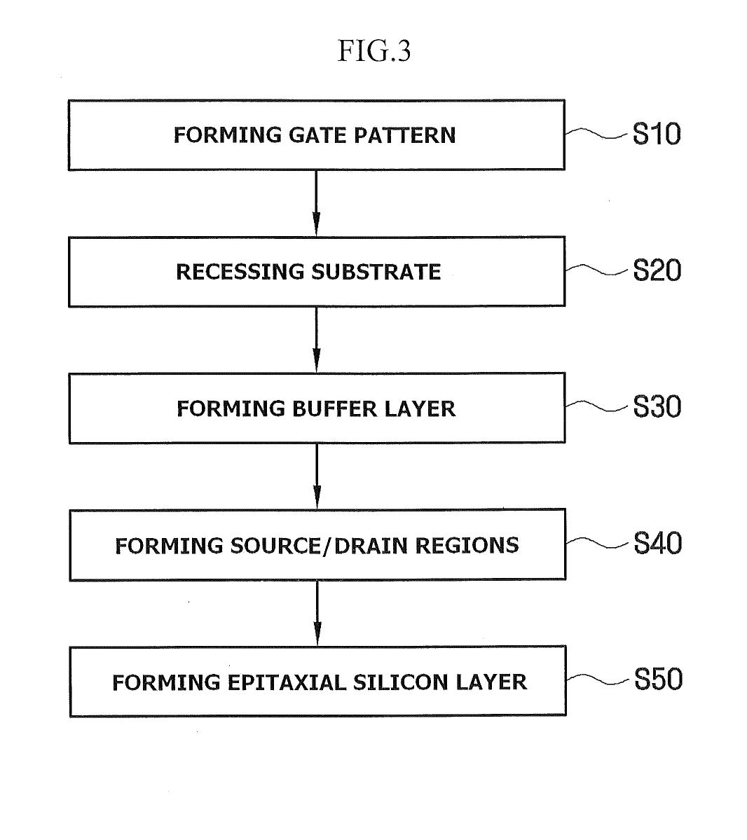

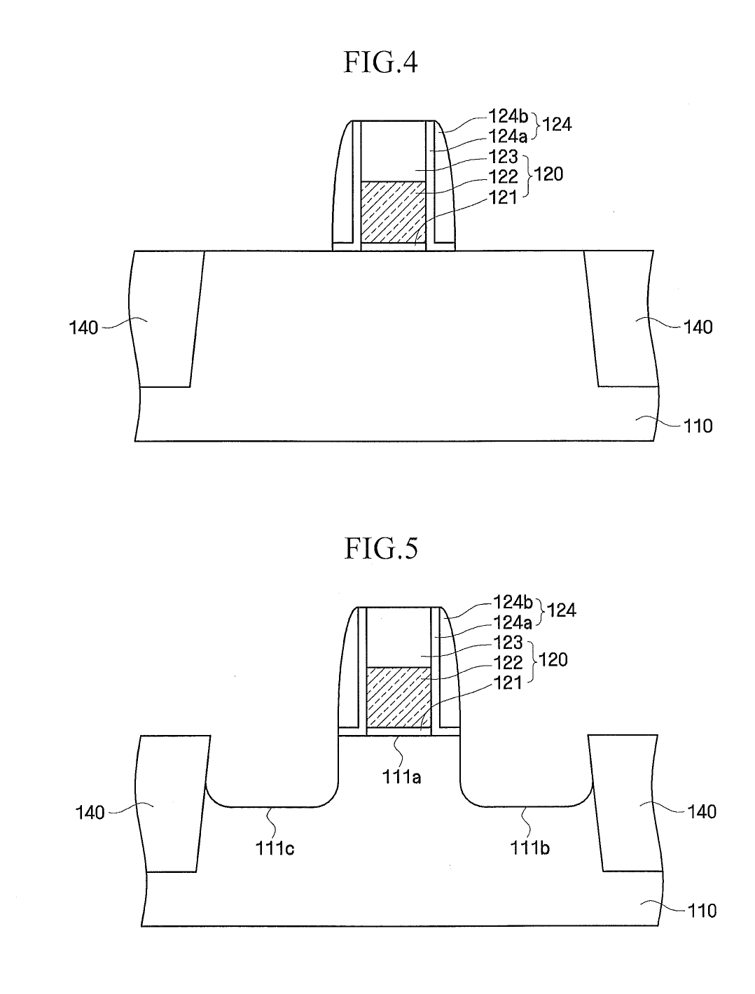

Processing steps in the fabrication of semiconductor devices in accordance with some embodiments of the present inventive concept will be discussed with respect to FIGS. 3-8. FIG. 3 is a flowchart illustrating a manufacturing method of a semiconductor device in accordance with some embodiments of the present inventive concept. FIGS. 4 to 8 are cross-sections illustrating processing steps in the fabrication of semiconductor devices in accordance some embodiments of the present inventive concept. In the following description, well-known functions or constructions are not described in detail to avoid obscuring the inventive concept with unnecessary detail for those of ordinary skill in the art.

Referring first to FIG. 3, the manufacturing method of the semiconductor device according to some embodiments of the present inventive concept includes forming a gate pattern (S10), recessing a substrate (S20), forming a buffer layer (S30), forming a source region and a drain region (S40) and forming an epitaxial silicon layer (S50).

Referring now to FIG. 4, in S10, a gate pattern 120 having a gate insulating layer 121, a gate electrode 122 and a hard mask layer 123 sequentially stacked is formed on a substrate 110.

In particular, an insulating layer for forming a gate insulating layer, a conductive layer for forming a gate electrode and an insulating layer for forming a hard mask layer are sequentially deposited on the substrate 110, and patterned using photolithography, thereby forming the gate pattern 120 having the gate insulating layer 121, the gate electrode 122 and the hard mask layer 123 sequentially stacked. In some embodiments, the hard mask layer 123 may be omitted without departing from the scope of the present inventive concept.

The substrate 110 may be a silicon substrate, a Silicon On Insulator (SOI) substrate, a gallium arsenic substrate, a silicon germanium (SiGe) substrate, a ceramic substrate, a quartz substrate, or a glass substrate for a display. Furthermore, a P-type substrate or an N-type substrate may be used as a semiconductor substrate 100. Although not shown, the substrate 110 may a p-type well or an n-type well doped with a p-type or an n-type impurity, respectively.

The gate insulating layer 121 and the hard mask layer 123 may be formed of silicon oxide (SiOₓ), silicon oxynitride (SiON), titanium oxide (TiOₓ), or tantalum oxide (TaOₓ), but not limited thereto. The gate electrode 122 is a conductor and may have a stacked structure of at least one of an n-type or p-type impurity doped polysilicon layer, a metal layer, a metal silicide layer, or a metal nitride layer. Examples of the useful metal for the gate electrode 122 may include, but not limited to, cobalt (Co), nickel (Ni), titanium (Ti), and tantalum (Ta).

The gate insulating layer 121, the gate electrode 122 and the hard mask layer 123 may be sequentially stacked using chemical vapor deposition (CVD) or sputtering, but not limited thereto.

Although not specifically illustrated in this embodiment, before forming the gate pattern 120, an isolation layer 140 may be formed on the substrate 110 to define an active region and a non-active region. The isolation layer 140 may be formed by, for example, a shallow trench isolation (STI) or a field oxide (FOX) technique.

After the forming of the gate pattern 120, a gate spacer 124 is formed on the sidewalls of the gate pattern 120 to protect the gate electrode 122. The gate spacer 124 may be formed of an oxide layer or a nitride layer, or may have a dual layered structure of an oxide layer and a nitride layer. An oxide layer 124a is formed on the sidewalls of the gate pattern 120 and extends toward the active region of the substrate 110 through oxidation. A nitride layer 124b is formed by depositing an insulating material on the entire surface of the resultant structure having the gate pattern 120 and the oxide layer 124a by, for example, CVD, followed by anisotropically etching

Referring now to FIG. 5, in S20, the substrate 110 is etched using the gate pattern 120 and the gate spacer 124 as etch masks to form a trench.

In particular, the substrate at opposite sides of the gate pattern 120 and the gate spacer 124 is isotropically or anisotropically etched using the gate pattern 120 and the gate spacer 124 as etch masks, thereby forming a trench. Here, a combination of O₂, CF₄, or Cl₂ may be used as an etching gas. In addition, the etching is performed to a depth of 10 to 50 nm.

As the result of the etching, the substrate 110 may have a first surface 111a, which is not recessed, and has a gate pattern 120 formed thereon, and second surfaces 111b and 111c which are recessed. The recessed second surfaces 111b and 111c are regions where the source region 132 and the drain region 133 are to be formed. A channel region is formed under the first surface 111 a having the gate pattern 120 formed thereon.

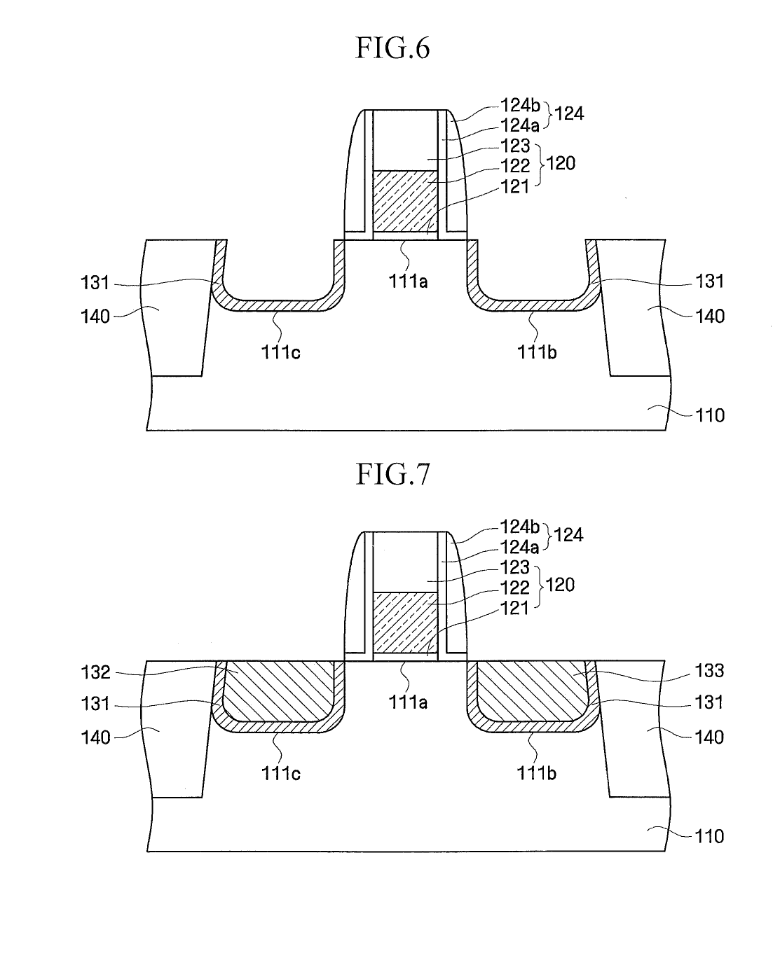

Referring now to FIG. 6, in S30, a carbon-doped silicon buffer layer 131 is formed on the recessed second surfaces 111b and 111c by selective epitaxial growth.

In particular, in order to clean the recessed second surfaces 111b and 111c, the recessed second surfaces 111b and 111c are pretreated with, for example, a HF solution, and SiH₃CH₃ and CH₄ or C₂H₆ gas is supplied at a temperature of 400-650° C., thereby forming the carbon-doped silicon buffer layer 131 by selective epitaxial growth.

In such a manner, the silicon buffer layer 131 made of silicon carbide can be formed on the recessed second surfaces 111b and 111c. The silicon buffer layer 131 may be formed to a thickness of 1 to 20 nm.

The silicon buffer layer 131 reduces or possibly prevents excessive diffusion of dopant existing in the source region and the drain region, thereby improving the short channel effect and possibly preventing a junction depth from increasing due to the dopant diffusion. Furthermore, since the silicon buffer layer 131 is formed while carbon is doped by epitaxial growth, the process is simplified compared to a case of using an ion implantation process. Additionally, since the lattice damage is mitigated, dopant diffusion can be further suppressed.

Referring to FIG. 7, in S40, a dopant-containing silicon layer is formed on the silicon buffer layer 131 by epitaxial growth. In particular, a silicon layer or a silicon germanium layer doped with an n-type dopant or a p-type dopant is formed on the silicon buffer layer 131 by selective epitaxial growth. In particular, in embodiments of an NMOS device, a silicon layer doped with an n-type dopant is formed on the silicon buffer layer 131 using Si₂H₆, SiH₄, SiH₂Cl₂ or Si₃H₈ gas as a silicon (Si) source and PH₃ as an n-type dopant source by selective epitaxial growth using, for example, low pressure chemical vapor deposition (LPCVD) or ultrahigh vacuum chemical vapor deposition (UHVCVD). In embodiments of a PMOS device, a silicon germanium layer doped with a p-type dopant is formed on the silicon buffer layer 131 using Si₂H₆, SiH₄, SiH₂Cl₂ or Si₃H₈ gas as a silicon (Si) source, GeH₄ gas as a Ge source gas, and B₂H₆ gas as a dopant gas by selective epitaxial growth. Here, the selective epitaxial growth is performed at a temperature of from about 400 to about 650° C. using HCl gas as an etching gas.

The selective epitaxial growth process for forming the source region 132 and the drain region 133 is performed in situ with the selective epitaxial growth process for forming the silicon buffer layer 131. In particular, SiH₃CH₃ and CH₄ or C₂H₆ gas is supplied to form a silicon carbide layer by selective epitaxial growth, and the selective epitaxial growth is further performed in the same chamber with only the kind of a source gas changed, thereby forming the silicon layer or silicon germanium layer doped with a dopant.

In addition, the source region 132 and the drain region 133 may be formed at the same height as the first surface 111 a or lower than a top surface of a gate insulating layer 121 by selective epitaxial growth. FIG. 7 illustrates embodiments where the source region 132 and the drain region 133 may be formed at the same height as the first surface 111a.

As discussed above, since the dopant of the source region 132 and the drain region 133 is doped in situ in the epitaxial process, it is not necessary to implant the dopant in a subsequent ion implantation process, thereby simplifying the process. Furthermore, the epitaxial growth can suppress the impurity diffusion and can reduce the lattice damage, unlike in the ion implantation process in which the lattice damage may be induced and impurity diffusion may be excessively performed.

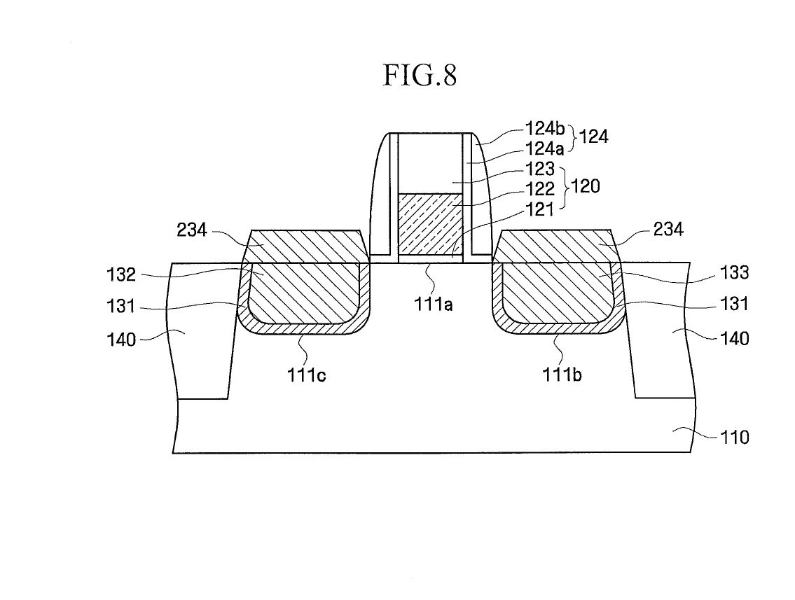

Referring to FIG. 8, in S50, a silicon layer 234 doped with an n-type dopant or a p-type dopant is formed on the source region 132 and the drain region 133 to be higher than a top surface of the gate insulating layer 121 by selective epitaxial growth. In particular, the silicon layer 234 doped with an n-type dopant or a p-type dopant is formed on the source region 132 and the drain region 133 in the same manner as in the step S40 of forming the source region 132 and the drain region 133.

An n-type dopant or p-type dopant concentration of the epitaxial silicon layer 234 is higher than that of the source region 132 and the drain region 133. When the dopant concentration of the epitaxial silicon layer 234 is higher than that of the source region 232 and the drain region 233, contact resistance can be reduced.

Furthermore, the epitaxial silicon layer 234 is formed to be higher than the top surface of the gate insulating layer 121. In these embodiments, ultra shallow junctions can be advantageously formed.

The step S50 of forming the epitaxial silicon layer 234 may be omitted in some embodiments without departing from the scope of the present inventive concept. In these embodiments, in S40, the source region 132 and the drain region 133 are formed to be higher than the top surface of the gate insulating layer 121. However, in embodiments where the step S50 is not omitted, that is, when the epitaxial silicon layer 234 is formed, the source region 132 and the drain region 133 may be formed at the same height as the first surface 111a, and the epitaxial silicon layer 234 may be formed to be higher than the top surface of the gate insulating layer 121.

Various examples will now be discussed to more particularly illustrate the effects and advantages of the inventive concept, and should not be construed as limiting the scope of the inventive concept.

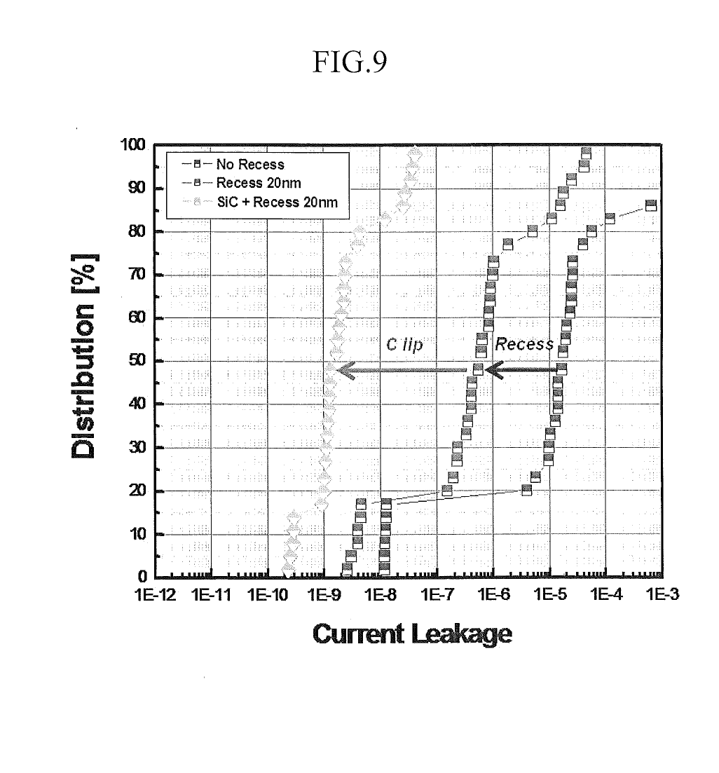

The first example, Evaluation Example 1, evaluates current leakage. A silicon substrate was recessed and source and drain regions doped with phosphorus (P) were formed on the recessed surface by selective epitaxial growth, thereby forming an NMOS device. Table 1 summarizes various parameters for evaluating current leakage levels of various NMOS devices fabricated according to Example 1 and Comparative Examples 1 and 2, including a recessed depth of the silicon substrate, an overgrown height relative to a gate insulating layer, and presence or absence of a carbon-doped silicon buffer layer. Concentrations of phosphorus (P) doped into the source and drain regions were in a range of 5E19-5E20. Relative current distributions (%) were measured at various locations of the thus-formed NMOS devices and current leakage levels thereof were observed. The measured current leakage levels of the respective semiconductor devices are shown in FIG. 9.

TABLE 1

| | Comparative | Comparative | |
|---|---|---|---|
| | Example 1 | Example 2 | Example 1 |
| Recessed depth (nm) | 0 | 20 | 20 |
| Overgrown height (nm) | 20 | 20 | 20 |
| Presence of silicon | x | x | ∘ |
| buffer layer | | | |

As illustrated in FIG. 9, a semiconductor device in which a source region and a drain region were formed with a substrate recessed to a depth of 20 nm (Comparative Example 2) exhibited a smaller current leakage level than a semiconductor device in which a source region and a drain region were formed with a substrate not recessed (Comparative Example 1). However, the semiconductor device according to Comparative Example 2 still showed a considerable amount of current leakage. By contrast, the semiconductor device according to Example 1 of the present inventive concept, in which the substrate was recessed to a depth of 20 nm and a carbon-doped silicon buffer layer was formed, showed a noticeably reduced current leakage level.

A high level of current leakage means excessive dopant diffused. Therefore, dopant diffusion can be suppressed by forming a carbon-doped silicon buffer layer. Furthermore, when the substrate is recessed, followed by forming a carbon-doped silicon buffer layer, like in Example 1, dopant diffusion can be further suppressed.

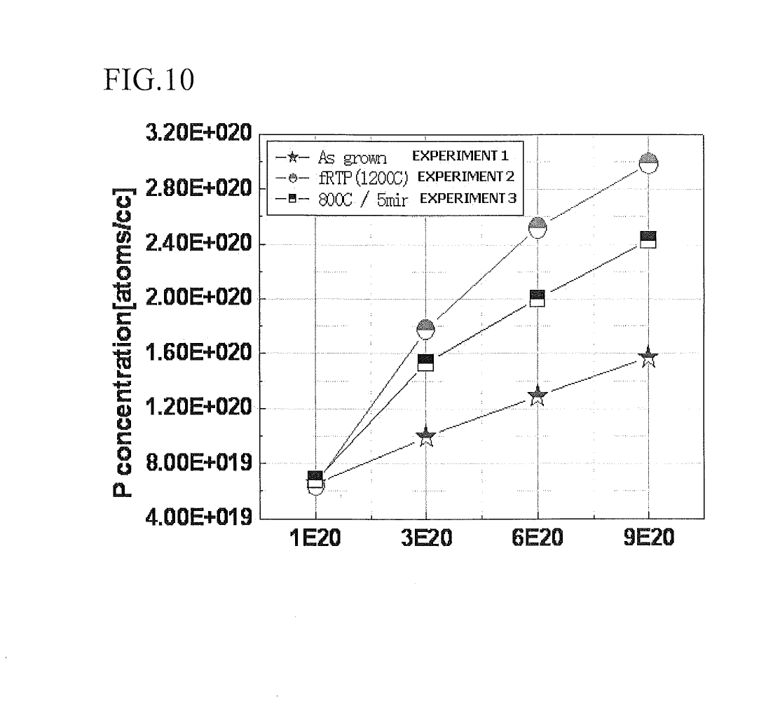

A second example, Evaluation Example 2 discusses concentrations of phosphorus (P) doped with selective epitaxial growth. In forming the NMOS device shown in FIG. 1, when phosphorus (P) was doped into a source region and a drain region by selective epitaxial growth (EXPERIMENT 1), and when phosphorus (P) was doped into a source region and a drain region by selective epitaxial growth, followed by annealing (EXPERIMENTS 2 and 3), overall concentrations of doped phosphorus (P) and concentrations of activated phosphorus (P) were measured. The measurement results are shown in FIG. 10. Here, “phosphorus (P) being activated” means that phosphorus (P) as an impurity is implanted into substitial sites of a silicon crystal lattice.

If a concentration of activated phosphorus (P) is approximately 1.0×10²⁰ atoms/cc in implanting phosphorus (P) into a silicon layer by a selective epitaxial process to form a source region and a drain region, it is not necessary to perform a separate ion implantation process. As shown in FIG. 10, when phosphorus (P) was doped by selective epitaxial growth, the doping concentration was approximately 1.0×10²⁰ atoms/cc, suggesting that the concentration of phosphorus (P) was maintained at a suitable level for forming an NMOS.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A manufacturing method of a semiconductor device comprising:
forming a gate pattern on a substrate, the gate pattern including a gate insulating layer and a gate electrode;
forming a recessed surface by etching the substrate of both sides of the gate pattern;
forming a carbon-doped silicon buffer layer on the recessed surface using selective epitaxial growth; and
forming source and drain region doped with an n-type dopant or a p-type dopant on the silicon buffer layer.

2. The manufacturing method of claim 1, wherein the silicon buffer layer has a thickness of from about to 1.0 nm to about 20 nm.

3. The manufacturing method of claim 1, wherein the silicon buffer layer is formed along the recessed surface.

4. The manufacturing method of claim 1, wherein the silicon buffer layer includes silicon carbide.

5. The manufacturing method of claim 1, wherein the source and drain region is phosphorus (P) doped silicon layer.

6. The manufacturing method of claim 1, wherein the source and drain region is boron (B) doped silicon germanium (SiGe) layer.

7. The manufacturing method of claim 1, wherein a top surface of the source and drain region is higher than a top surface of the gate insulating layer and lower than a top surface of the gate electrode.

8. The manufacturing method of claim 1, further comprising an epitaxial silicon layer doped with an n-type dopant or a p-type dopant on the source and drain region, and
wherein a top surface of epitaxial silicon layer is at least 20 nm higher than a top surface of the gate insulating layer and lower than a top surface of the gate electrode.

9. A manufacturing method of a semiconductor device comprising:
forming a gate pattern on a substrate, the gate pattern including a gate insulating layer and a gate electrode;
forming a recessed surface by etching the substrate of both sides of the gate pattern;
forming a carbon-doped silicon buffer layer on the recessed surface; and
forming source and drain region doped with an n-type dopant or a p-type dopant on the silicon buffer layer, the source and drain region being formed in situ with and the silicon buffer layer.

10. The manufacturing method of claim 9, wherein the forming the source and drain region and the silicon buffer layer are performed in situ within the same chamber a variation of a source gas.

11. The manufacturing method of claim 9, wherein the silicon buffer layer has a thickness of from about to 1.0 nm to about 20 nm.

12. The manufacturing method of claim 9, wherein the source and drain region and the silicon buffer layer are formed by using selective epitaxial growth.

13. The manufacturing method of claim 9, wherein the n-type dopant or a p-type dopant is doped in situ during forming the source and drain region.

14. The manufacturing method of claim 9, further comprising an epitaxial silicon layer doped with an n-type dopant or a p-type dopant on the source and drain region.

15. The manufacturing method of claim 14, wherein the epitaxial silicon layer is formed in situ with the source and drain region.

16. The manufacturing method of claim 14, wherein an n-type dopant or a p-type dopant concentration of the epitaxial silicon layer is higher than that of the source and drain region.

17. A manufacturing method of a semiconductor device comprising:
forming a gate pattern and a gate spacer disposed at sidewalls of the gate pattern on a substrate, the gate pattern including a gate insulating layer and a gate electrode;
forming a recessed surface by etching the substrate of both sides of the gate pattern and the gate spacer;
forming a carbon-doped silicon buffer layer on the recessed surface; and
forming source and drain region doped with an n-type dopant or p-type dopant on the silicon buffer layer using selective epitaxial growth.

18. The manufacturing method of claim 17, further comprising an epitaxial silicon layer doped with an n-type dopant or a p-type dopant on the source and drain region to be elevated from a top surface of the gate insulating layer using selective epitaxial growth.

19. The manufacturing method of claim 17, wherein the silicon buffer layer is formed by selective epitaxial growth.

20. The manufacturing method of claim 17, wherein the silicon buffer layer has a thickness of from about to 1.0 nm to about 20 nm.
